(19) United States
(12) Patent Application Publication
(10) Pub. No.: US 2024/0388276 A1
(43) Pub. Date: Nov. 21, 2024

(54) FILTER UNIT AND MANUFACTURING METHOD THEREFOR, AND ELECTRONIC DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventors: Qiuxu Wei, Beijing (CN); Yue Li, Beijing (CN); Lihui Wang, Beijing (CN); Yanfei Ren, Beijing (CN); Taonan Zhang, Beijing (CN); Yuelei Xiao, Beijing (CN); Yifan Wu, Beijing (CN); Yulin Feng, Beijing (CN); Xue Cao, Beijing (CN); Kidong Han, Beijing (CN); Qichang An, Beijing (CN); Wenbo Chang, Beijing (CN); Huiying Li, Beijing (CN); Feng Qu, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 18/271,105

(22) PCT Filed: Jul. 18, 2022
(86) PCT No.: PCT/CN2022/106158

§ 371 Date: Jul. 6, 2023

(51) Int. Cl. H03H 9/17; H03H 3/02; H03H 9/05; H03H 9/56

(52) U.S. Cl. CPC H03H 9/173; H03H 3/02; H03H 9/05; H03H 9/568; H03H 2003/021

(57) ABSTRACT

The present disclosure provides a filter unit and a manufacturing method therefor, and an electronic device, relating to the technical field of radio frequency micro-electromechanical systems. The filter unit includes a resonant structure; and a substrate disposed at one side of the resonant structure, the substrate including a modified structure and a supporting structure surrounding the modified structure, and a cavity being formed between the modified structure and the resonant structure. The filter unit provided in the present disclosure can greatly simplify the process manufacturing flow and reduce the process manufacturing procedure difficulty by forming a cavity between the modified structure and the resonant structure.

### TECHNICAL FIELD

The present disclosure relates to the technical field of radio frequency micro-electromechanical systems and, more particularly, to a filter unit, a manufacturing method therefor and an electronic device.

### BACKGROUND

Filters as important radio frequency components play a pivotal role in the field of communication. With the development of technology, film bulk acoustic resonator (FBAR) technology has become the mainstream technology of radio frequency filters, wherein the FBAR includes air-gap type FBAR.

The current air-gap type FBAR is often made by the method of depositing a sacrificial layer. However, the conventional treatment process of a sacrificial layer is very harsh, resulting in that the manufacturing process of the air-gap type FBAR is very complicated, which is not conducive to industrial production.

### SUMMARY

The embodiments of the present disclosure adopt the following technical solutions.

In one aspect, an embodiment of the present disclosure provides a filter unit, including:
a resonant structure; and
a substrate disposed at one side of the resonant structure, the substrate including a modified structure and a supporting structure surrounding the modified structure, and a cavity being formed between the modified structure and the resonant structure.

Optionally, a boundary of an orthographic projection of the resonant structure on the substrate intersects or overlaps with the supporting structure; and

a surface of the modified structure close to one side of the resonant structure includes at least one cambered surface.

Optionally, the resonant structure includes at least one through hole communicating with the cavity, a boundary of an orthographic projection of the through hole on the substrate intersecting or overlapping with the modified structure; a geometric center of a space occupied by the through hole is collinear with a spherical center of the cambered surface.

Optionally, the spherical center of the cambered surface is located where the through hole communicates with the cavity.

Optionally, a quantity of the cambered surfaces is the same as a quantity of the through holes.

Optionally, a surface of the supporting structure close to one side of the modified structure includes an annular surface, a shape of a space enclosed by an edge of the annular surface close to one side of the resonant structure includes a polygon having rounded corners, and a quantity of edge lengths of the polygon having the rounded corners is the same as a quantity of the through holes and a quantity of the cambered surfaces.

Optionally, the resonant structure has five through holes, the surface of the modified structure close to one side of the resonant structure includes five cambered surfaces, and the polygon having the rounded corners includes a pentagon having rounded corners.

Optionally, a distance between a junction of five cambered surfaces and the resonant structure is less than the distance between a position of the cambered surface corresponding to each through hole and the resonant structure.

Optionally, the resonant structure has four through holes, the surface of the modified structure close to one side of the resonant structure includes four cambered surfaces, and the polygon having the rounded corners includes a quadrangle having rounded corners; or

the resonant structure has three through holes, the surface of the modified structure close to one side of the resonant structure includes three cambered surfaces, and the polygon having the rounded corners includes a triangle having rounded corners.

Optionally, the annular surface includes a first annular surface and a second annular surface connected to each other, and the second annular surface is located between the first annular surface and the resonant structure; a part of the first annular surface is in direct contact with the modified structure; and the first annular surface is non-coplanar with the second annular surface.

Optionally, a space occupied by the first annular surface is less than a space occupied by the second annular surface.

Optionally, an included angle between the second annular surface and one side of the resonant structure close to the substrate has a range from eighty degrees to eighty-eight degrees.

Optionally, an etching rate of a material of the modified structure is greater than an etching rate of a material of the supporting structure.

Optionally, the filter unit further includes a supporting layer disposed between the modified structure and the resonant structure; and
the through hole further penetrates through the supporting layer and communicates with the cavity.

Optionally, a material of the modified structure includes glass.

In another aspect, an embodiment of the present disclosure provides an electronic device including at least three filter units stated above, wherein at least two of the at least three filter units are connected in series and are connected in parallel with the filter units other than the filter units connected in series.

In another aspect, an embodiment of the present disclosure provides a manufacturing method for the filter unit stated above, wherein the method includes:
forming the substrate; and
forming the resonant structure at one side of the substrate, wherein there is the cavity between the resonant structure and the substrate.

Optionally, forming the substrate includes:
providing the substrate; and
modifying the substrate to form a modified portion and a supporting structure, wherein the supporting structure surrounds the modified portion.

Optionally, forming the resonant structure at one side of the substrate, wherein there is the cavity between the resonant structure and the substrate includes:
forming at least one through hole on the resonant structure; and
injecting corrosive liquid through the through hole to corrode the modified portion to form a modified structure and the cavity between the modified structure and the resonant structure.

The above description is only an overview of the technical solution of the present disclosure, in order to be able to better understand the technical means of the present disclosure, and the solution can be implemented in accordance with the content of the description, and in order to make the above and other purposes, features and advantages of the present disclosure more obvious and easy to understand, the following specific embodiments of the present disclosure are hereby given.

### BRIEF DESCRIPTION OF THE DRAWINGS

In order to more clearly illustrate the embodiment of the present disclosure or the technical solution in the related art, the following will be a brief introduction to the drawings required in descripting the embodiment or prior art, obviously, the drawings described below are only some embodiments of the present disclosure, for those of ordinary skill in the art, without the premise of paying creative labor, may also obtain other drawings according to these drawings.

FIGS. 1 to 4 show a manufacturing procedure of an air-gap type FBAR in a related art according to an embodiment of the present disclosure;

FIG. 5 is a schematic structural diagram of a filter unit according to an embodiment of the present disclosure;

FIG. 6 is a top view of a modified structure in a filter unit according to an embodiment of the present disclosure;

FIG. 7 is a perspective diagram of a substrate in a filter unit according to an embodiment of the present disclosure;

FIG. 8 is a cross-sectional view of a substrate in a filter unit according to an embodiment of the present disclosure;

FIG. 9 is a view showing various shapes of a surface of a modified structure close to one side of a resonant structure in a filter unit according to an embodiment of the present disclosure;

FIGS. 10 to 12 are the manufacturing processes of a filter unit according to an embodiment of the present disclosure; and

FIG. 13 is a schematic structural diagram of an electronic device according to an embodiment of the present disclosure.

### DETAILED DESCRIPTION OF THE EMBODIMENTS

In order to make the purpose, technical solution and advantages of embodiments of the present disclosure clearer, the following will be combined with the accompanying drawings in the embodiments of the present disclosure, the technical solutions in the embodiments of the present disclosure are clearly and completely described, obviously, the described embodiments are a part of the embodiments of the present disclosure, not all embodiments. Based on the embodiments in the present disclosure, all other embodiments obtained by those of ordinary skill in the art without paying creative labor are within the scope of protection of the present disclosure.

In the figures, the thickness of the area and layer may be exaggerated for clarity. The same drawing marks in the figures indicate the same or similar structures, so their detailed description will be omitted. Further, the drawings are only illustrative illustrations of the present disclosure and are not necessarily drawn to scale.

In embodiments of the present disclosure, unless otherwise indicated, “plurality” means two or more; The orientation or position relationship indicated by the term “above” is based on the orientation or position relationship shown in the drawings, and is only intended to facilitate the description of the present disclosure and simplify the description, and does not indicate or imply that the structure or element referred to must have a specific orientation, be constructed and operated in a specific orientation, and therefore cannot be understood as a limitation of the present disclosure.

Unless the context requires, otherwise, throughout the whole description and claims, the term “including” is interpreted to mean open, inclusive, i.e. “including, but not limited to”. In the description of the specification, the terms “one embodiment”, “some embodiments”, “exemplary embodiments”, “examples”, “specific examples” or “some examples” and the like are intended to indicate that a particular feature, a structure, a material or a characteristic associated with the embodiment or the example is included in at least one embodiment or example of the present disclosure. The schematic representation of the above terms does not necessarily refer to the same embodiment or example. Further, the particular features, structures, materials or characteristics may be included in any one or more embodiments or examples in any appropriate manner.

In embodiments of the present disclosure, the words “first”, “second” and the like are used to distinguish the same or similar terms with substantially the same function and effect, only to clearly describe the technical solution of the embodiment of the present disclosure, and cannot be understood as indicating or implying relative importance or implicitly indicating the number of technical features indicated.

With the development of modern wireless communication technology to high-frequency, high-speed, and other directions, the common front-end filters for radio frequency communication are surfaced with higher requirements. As a new filter, FBAR is widely used in the fifth-generation (5G) communication. According to different device structures, the FBAR can be divided into two categories: back-engraved type and air-gap type. Back-engraved type FBAR has poor structural stability and low yield. Compared with back-engraved type FBAR, air-gap type FBAR has better mechanical reliability and is more widely used.

The current air-gap type FBAR includes a substrate and an electrode-piezoelectric film-electrode structure disposed on the substrate. When a voltage is applied to two electrodes, the piezoelectric effect converts electric energy into mechanical energy, thereby making the piezoelectric film undergo mechanical deformation to excite bulk acoustic waves within the piezoelectric film body. In order to reduce the loss of acoustic waves, it is necessary to make the acoustic waves form total reflection. Since the acoustic impedance of air can be considered to be approximately zero, therefore, two electrode surfaces in contact with air when making the air-gap type FBAR. In the air-gap type FBAR, one electrode far away from the substrate must be in contact with air, while one electrode close to the substrate, due to its growth on the substrate, needs to use an etching method to remove at least part of the substrate material at the electrode such that the electrode can not only be in contact with air, but also can ensure sufficient mechanical strength, i.e. an air-gap type film bulk acoustic resonator is manufactured.

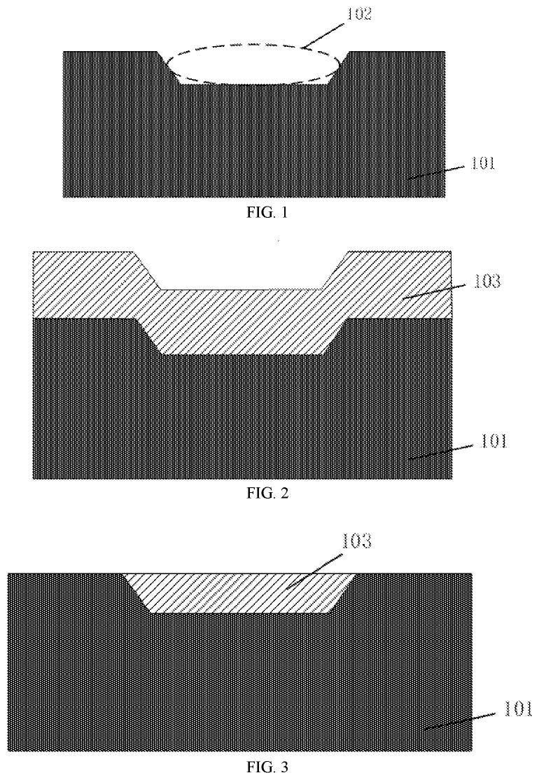

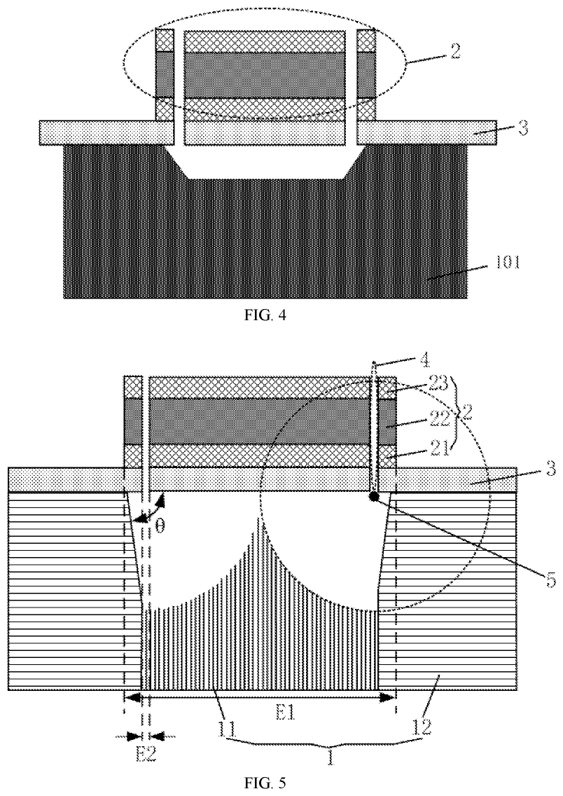

The manufacturing method for a mainstream air-gap type film bulk acoustic resonator is as shown in FIGS. 1 to 4. Firstly, as shown in FIG. 1, a groove 102 is formed by etching on the surface of a monocrystalline silicon substrate 101; next, as shown in FIG. 2, silicon oxide or phosphorus-doped silicon oxide (PSG) is deposited at the groove to form a sacrificial layer 103; then, as shown in FIG. 3, the excess material of the sacrificial layer 103 is ground and polished by using the chemical mechanical polishing (CMP) process to form a flat bottom surface structure; finally, as shown in FIG. 4, sequential laminating is performed on a substrate having a sacrificial layer to form a supporting layer 3 and a resonant structure 2, and a through hole is formed on the resonant structure 3; through the through hole, the corrosion liquid contacts the sacrificial layer and then corrodes the sacrificial layer to remove the sacrificial layer, thereby forming a cavity as shown in FIG. 4, that is, the air-gap type film bulk acoustic resonator in the related art is obtained.

However, in order to obtain a better crystalline film layer quality for the film layer in the resonant structure, the requirements for the flatness of the surface of the film layer treated by the above-mentioned CMP process are very strict, for example, it is required that the roughness of the surface of the film layer is less than 0.5 nm and the sinking caused by the CMP dish effect is less than 50 nm, etc. which inevitably makes the manufacturing process of the air-gap type film bulk acoustic resonator complicated and is not conducive to industrial production.

Based on the above, an embodiment of the present disclosure provides a filter unit. With reference to FIG. 5, the filter unit includes a resonant structure 2.

A substrate 1 is disposed at one side of the resonant structure 2, and the substrate 1 includes a modified structure 11 and a supporting structure 12 surrounding the modified structure 11. A cavity is formed between the modified structure 11 and the resonant structure 2.

The specific structure of the above-mentioned resonant structure is not limited. As an example, with reference to FIG. 5, the above-mentioned resonant structure may include a first electrode 21, a piezoelectric layer 22, and a second electrode 23 which are sequentially arranged in layer configuration. When a voltage (for example, an alternating voltage) is applied to the first 30) electrode 21 and the second electrode 23, the piezoelectric effect converts the electric energy into mechanical energy, thereby making the piezoelectric layer 22 undergo mechanical deformation, thus exciting a bulk acoustic wave in the body of the piezoelectric layer 22. The bulk acoustic wave vibrates at a cavity formed between the modified structure 11 and the resonant structure 2, to perform propagation.

The material, thickness, manufacturing process, etc. of the above-mentioned first electrode and second electrode are not specifically limited herein. As an example, the materials of the first electrode and the second electrode may include a high acoustic resistance material, for example, molybdenum, tungsten, etc. for applying electrical signal excitation to the piezoelectric layer. As an example, the first electrode and the second electrode may have a thickness ranging from 200 nm-600 nm in a direction perpendicular to the substrate. Specifically, the first electrode and the second electrode may have a thickness of 200 nm, 400 nm, 500 nm, 600 nm, etc. in the direction perpendicular to the substrate. As an example, the manufacturing processes for the first electrode and the second electrode may include physical vapor deposition (PVD), patterning, etc.

The material, thickness, manufacturing process, etc. of the above-mentioned piezoelectric layer are not specifically limited herein. As an example, the material of the piezoelectric layer may include aluminum nitride, scandium aluminum nitride, or the like, for receiving an electrical signal excitation generated by the two electrodes to form a mechanical resonance. As an example, the thickness of the piezoelectric layer in the direction perpendicular to the substrate may range from 500 nm to 2000 nm. Specifically, the thickness of the piezoelectric layer in the direction perpendicular to the substrate may be 500 nm, 1000 nm, 1500 nm, or 2000 nm, etc. As an example, the manufacturing process for the piezoelectric layer may include PVD, metal organic chemical vapor deposition (MOCVD), patterning, etc.

The material, thickness, and the like of the above-mentioned substrate are not specifically limited herein. As an example, the material of the substrate may include glass, so that a filter unit has properties of low dielectric loss and high resistivity, helping to improve the insertion loss performance of the filter unit. As an example, the thickness of the substrate may range from 30 μm to 200 μm. Specifically, the thickness of the substrate may be 30 μm, 50 μm, 80 μm, 110 μm, 150 μm, or 200 μm, etc.

The above-mentioned modified structure is located in the substrate, and the modified structure refers to a structure that has been subjected to a modification process such that its etching rate is much higher than the etching rate of the non-modified portion (namely, a supporting structure). Now, taking the material of the substrate as glass as an example, the formation principle of the modified structure and the supporting structure is specifically explained as follows: a portion of the glass substrate is modified (for example, performing laser-induced etching modification), and the Si—O molecular bond inside the glass can be broken by the modification process, so that the etching rate of the material of the portion treated by the modification process is greater than the etching rate of the material of the portion on the substrate not treated by the modification process, namely, the etching rate of the material of the modified structure is greater than the etching rate of the material of the supporting structure.

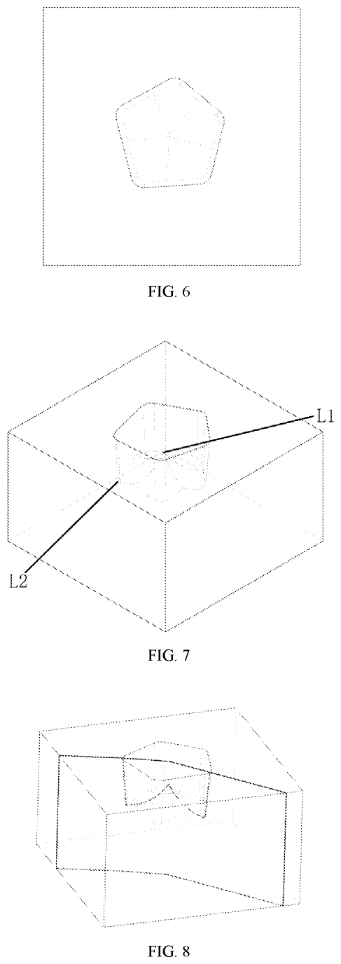

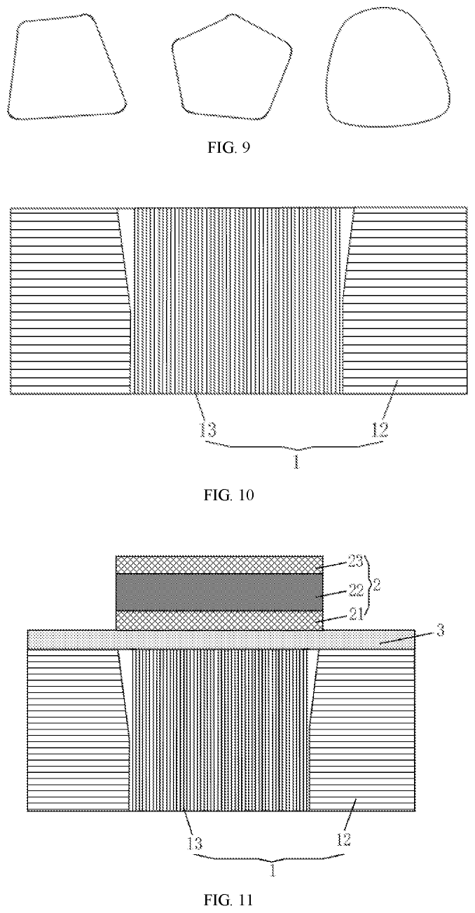

The shape of the cavity formed between the above-mentioned modified structure and the resonant structure is not specifically limited herein. As an example, with reference to FIGS. 6 to 8, the shape of the above-mentioned cavity may be petaloid, at this moment, the bottom surface of the cavity (the surface of the cavity close to one side of the modified structure) includes at least one cambered surface, and the top surface of the cavity (the surface of the cavity close to one side of the resonant structure) includes a rounded corner structure. The rounded corner structure may include a polygon with a rounded corner, such as a circular arc shape; and rounded corner quadrilaterals, rounded corner pentagons, a rounded corner trilateral, etc. as shown in FIG. 9.

Embodiments of the present disclosure provide a filter unit including: a resonant structure; and a substrate disposed at one side of the resonant structure. The substrate includes a modified structure and a supporting structure surrounding the modified structure, and a cavity is formed between the modified structure and the resonant structure. In this way, compared with the conventional method of first forming a groove on the silicon substrate, and then forming and a cavity is formed after removing a sacrificial layer, the filter unit provided by the embodiments of the present disclosure omits the sacrificial layer and thus omits the CMP process, thereby greatly simplifying the process manufacturing flow and reducing the processing manufacturing procedure difficulty. Then, the filter unit provided in the embodiments of the present disclosure forms a resonant structure directly on a substrate, and the substrate can be treated after the resonant structure is formed, so that a cavity is formed between the modified structure and the resonant structure, thereby avoiding the use of a sacrificial layer treatment process with strict requirement, simplifying the manufacturing process of the cavity in the filter unit, and reducing the processing requirements for the filter unit, which is very advantageous for industrial production.

Optionally, with reference to FIG. 5, a boundary of an orthographic projection E1 of the resonant structure 2 on the substrate 1 intersects or overlaps with the supporting structure 12. Referring to FIGS. 6-8, the surface of the modified structure close to one side of the resonant structure includes at least one cambered surface.

The boundary of the orthographic projection of the above-mentioned resonant structure on the substrate intersecting or overlapping with the supporting structure means that with reference to FIG. 5, the boundary of the orthographic projection E1 of the resonant structure 2 on the substrate 1 entirely intersects or overlaps with the supporting structure 12; optionally, the boundary of the orthographic projection of the resonant structure on the substrate partially intersects or overlaps with the supporting structure as long as it is ensured that a cavity can be formed between the resonant structure and the modified structure.

The surface of the modified structure close to one side of the resonant structure includes at least one cambered surface, and the quantity of cambered surfaces is not specifically limited herein. As an example, FIG. 5 is illustrated by taking that the surface of the modified structure 11 close to one side of the resonant structure 2 includes two cambered surfaces as an example. FIGS. 6 to 8 are illustrated by taking that the surface of the modified structure close to one side of the resonant structure includes five cambered surfaces as an example, at this moment, the top surface of the cavity includes a rounded corner pentagon.

In the filter unit provided in the embodiments of the present disclosure, since the boundary of the orthographic projection of the resonant structure on the substrate intersects or overlaps with the supporting structure, the supporting structure can support the resonant structure very well such that while ensuring the formation of a cavity between the resonant structure and the modified structure, it can also be ensured that the filter unit has sufficient mechanical strength.

Optionally, with reference to FIG. 5, the resonant structure 2 includes at least one through hole 4 in communication with the cavity, and the boundary of the orthographic projection E2 of the through hole 4 on the substrate 1 intersects or overlaps with the modified structure 11; the geometric center of the space occupied by the through hole 4 is collinear with the spherical center 5 of the cambered surface. Therefore, the edge length, position, etc. of the cambered surface of the surface of the modified structure close to one side of the resonant structure can be obtained by the position of the through hole.

The through hole is configured to make that the corrosive liquid flows into and corrodes the substrate to form the modified structure. The above-mentioned resonant structure includes at least one through hole, and the quantity of through holes is not specifically limited herein. As an example, FIG. 5 is illustrated by taking that the resonant structure 2 includes two through holes 4 as an example, and the quantity and the positions of the through holes can determine the side length, the quantity of spherical centers, the position, etc. of the cambered surface of the surface of the modified structure close to one side of the resonant structure.

The above-mentioned through hole is in communication with the cavity. That is because corrosive liquid flows into the through hole and corrodes the substrate after being in contact with the substrate, thereby forming a modified structure and a cavity between the modified structure and the resonant structure. At this point, the through hole is inevitably connected to the cavity.

The boundary of the orthographic projection of the above-mentioned through hole on the substrate intersecting or overlapping with the modified structure means that the boundary of the modified structure is directly opposite to the through hole. Referring to FIG. 5, the boundary of the orthographic projection E2 of the through hole 4 on the substrate 1 entirely intersects or overlaps with the modified structure 11. Optionally, the boundary of the orthographic projection of the through hole on the substrate partially intersects or overlaps with the modified structure as long as it is ensured that the modified structure can be formed.

Optionally, with reference to FIG. 5, the spherical center 5 of the cambered surface is located where the through hole 4 communicates with the cavity. Therefore, the position of the spherical center of the cambered surface of the surface of the modified structure close to one side of the resonant structure can be obtained by the position of the through hole, and the side length, the position, etc. of the cambered surface can be obtained from the position of the spherical center.

Optionally, referring to FIGS. 5 and 6-8, the quantity of cambered surfaces is the same as the quantity of the through holes. Therefore, the position of the spherical center of the cambered surface of the surface of the modified structure close to one side of the resonant structure can be obtained by the position of the through hole, and the side length, the position, etc. of the cambered surface can be obtained from the position of the spherical center.

Optionally, due to the influence of the etching process, with reference to FIG. 5, the surface of the supporting structure 12 close to one side of the modified structure 11 includes an annular surface, and a shape of a space enclosed by the edge of the annular surface close to one side of the resonant structure 2 includes a polygon with rounded corners, the quantity of edge lengths of the polygon with rounded corners being the same as the quantity of through holes and the quantity of the cambered surfaces. Therefore, the edge length, number, position, etc. of the cambered surface of the surface of the modified structure close to one side of the resonant structure can be obtained by the position of the through hole.

Taking the substrate material as glass as an example, the corrosive liquid can corrode the glass substrate to form a cavity. The corrosion rate of the modified structure is fast, a cavity cambered surface structure is formed, and the corrosion rate of the adjacent area of the modified structure and the supporting structure is slow, and a cavity side surface structure is formed.

The specific shape of the above-mentioned polygon having rounded corners is not limited herein. As an example, with reference to FIG. 9, the shape of the polygon with rounded corners may include a rounded corner quadrilateral, a rounded corner pentagon, and a rounded corner trilateral. FIGS. 6 to 8 are illustrated by taking that the above polygon shapes with rounded corners include a rounded corner pentagon as an example.

The curvature radius of the polygon having rounded corners is not specifically limited herein. As an example, and with being limited by the glass laser-induced etching process, the curvature radius of the above-mentioned polygon with rounded corners has a range from 5 μm to 50 μm. Specifically, the curvature radius of the above-mentioned polygon with rounded corners has a range of 5 μm, 12 μm, 25 μm, 40 μm, or 50 μm, etc.

The quantity of the edge lengths of the polygons having rounded corners being the same as the quantity of the through holes and the quantity of the cambered surfaces means that one edge is formed on the top surface of the cavity formed by corroding the substrate by injecting corrosive liquid into any one of the through holes, and one edge is formed on the surface of the modified structure close to one side of the resonant structure, so that the quantity of the through holes is the same as the quantity of the edge lengths of the polygon having rounded corners, and the quantity of the through holes is the same as the quantity of the cambered surfaces.

Optionally, with reference to FIGS. 6-8, the resonant structure has five through holes, the surface of the modified structure close to one side of the resonant structure includes five cambered surfaces, and polygons with rounded corners include a pentagon with rounded corners. The filter unit thus forms a pentagonal cavity.

Optionally, with reference to FIGS. 7 and 8, the distance between the junction L1 of the five cambered surfaces and the resonant structure is less than the distance between the corresponding cambered surface position L2 of each through hole and the resonant structure. At this time, the junction of the five cambered surfaces is the highest point of the modified structure, and the cambered surface positions corresponding to the through holes are all the lowest points of the modified structure, so that the modified structure can form a petal-like shape, namely, the cavity forms a petal-like shape.

Optionally, with reference to FIG. 9, the resonant structure has four through holes, the surface of the modified structure close to one side of the resonant structure includes four cambered surfaces, and the polygon having rounded corners includes a quadrilateral having rounded corners. The filter unit thus forms a quadrangular cavity.

Alternatively, with reference to FIG. 9, the resonant structure has three through holes, the surface of the modified structure close to one side of the resonant structure includes three cambered surfaces, and the polygon having rounded corners includes a triangle having rounded corners. The filter unit thus forms a triangular cavity.

Optionally, due to the influence of the etching process, with reference to FIG. 5, the annular surface includes a first annular surface and a second annular surface connected to each other, the second annular surface being located between the first annular surface and the resonant structure; a portion of the first annular surface is in direct contact with the modified structure; the first annular surface is not coplanar with the second annular surface. Therefore, the included angle between the surface of the supporting structure close to one side of the modified structure and the resonant structure is not perpendicular.

The first annular surface being non-coplanar with the second annular surface means that the edge length of the first annular surface is not collinear with the edge length of the second annular surface.

Optionally, due to the influence of the etching process, as shown in FIG. 5, the space occupied by the first annular surface is less than that occupied by the second annular surface. The included angle between the second annular surface and the resonant structure is thus not perpendicular.

Optionally, due to the influence of the etching process, e.g. limited by the glass laser-induced etching process, referring to FIG. 5, the included angle θ between the second annular surface and one side of the resonant structure close to the substrate has a range from eighty degrees to eighty-eight degrees.

The range of the included angle θ between the second annular surface and one side of the resonant structure close to the substrate is not specifically limited herein. As an example, the included angle θ between the second annular surface and one side of the resonant structure close to the substrate may be eighty degrees, eighty-one degrees, eighty-three degrees, eighty-six degrees, eighty-eight degrees, etc.

The included angle between the above-mentioned second annular surface and one side of the resonant structure close to the substrate depends on the etching process. Specifically, when using a hydrofluoric acid at the room temperature to conduct the corrosion, the included angle between the second annular surface and one side of the resonant structure close to the substrate may have a range from eighty degrees to eighty-five degrees, for example: eighty degrees, eighty-three degrees, or eighty-five degrees, etc.; when using a 100° C. to 120° C. high-temperature sodium hydroxide to conduct the corrosion, the included angle between the second annular surface and one side of the resonant structure close to the substrate may range from eighty-five degrees to eighty-eight degrees, for example: eighty-five degrees, eighty-seven degrees, or eighty-eight degrees, etc. To obtain a better, closer to ninety degrees etching angle, a 100° C. to 120° C. high-temperature sodium hydroxide corrosion process may be chosen.

Optionally, the etching rate of the material of the modified structure is greater than the etching rate of the material of the supporting structure. Therefore, the filter unit provided in the embodiments of the present disclosure can treat the substrate after the resonant structure is formed, so that a cavity is formed between the modified structure and the resonant structure, thereby avoiding the use of a sacrificial layer treatment process with strict requirements, simplifying the manufacturing process of the cavity in the filter unit, and reducing the processing requirements for the filter unit, which is very advantageous for industrial production.

Now, taking the material of the substrate as glass as an example, the formation principle of the modified structure and the supporting structure is specifically explained as follows: a portion of the glass substrate is modified (for example, performing laser-induced etching modification), and the Si—O molecular bond inside the glass can be broken by the modification process, so that the etching rate of the material of the portion treated by the modification process is greater than the etching rate of the material of the portion on the substrate not treated by the modification process, namely, the etching rate of the material of the modified structure is greater than the etching rate of the material of the supporting structure.

Optionally, with reference to FIG. 5, the filter unit further includes a supporting layer 3, the supporting layer 3 being arranged between the modified structure 11 and the resonant structure 2; a through hole 4 also extends throughout the supporting layer 3 and communicates with the cavity. Therefore, the mechanical strength of the filter unit can be increased by the supporting layer, the risk of cracking in the resonant structure is reduced, and the crystalline quality of the piezoelectric layer in the resonant structure is improved.

The material, thickness, manufacturing process, and the like of the above-mentioned supporting layer are not specifically limited herein. Illustratively, the material of the supporting layer may include silicon nitride, aluminum nitride, and the like.

As an example, the thickness of the supporting layer in the direction perpendicular to the substrate may range from 100 nm to 300 nm. Specifically, the thickness of the supporting layer in the direction perpendicular to the substrate may be 100 nm, 150 nm, 200 nm, 250 nm, or 300 nm, etc.

Illustratively, the above-mentioned manufacturing process for the supporting layer may include low pressure chemical vapor deposition (LPCVD), plasma enhanced chemical vapor deposition (PECVD), PVD, etc. A silicon nitride supporting layer may be deposited by LPCVD or PECVD, or an aluminum nitride supporting layer may be deposited by using PVD.

Optionally, the material for the modified structure includes glass. Therefore, the embodiments of the present disclosure provide a glass substrate having lower dielectric loss and high resistivity characteristics than the single crystal silicon substrate of the related art, which is more helpful to improve the insertion loss performance of the filter unit.

The specific type of glass described above is not limited herein. Illustratively, the types of glass may include low dielectric loss glasses such as fused silica glass, alkali-free borosilicate glass, etc.

Embodiments of the present disclosure also provide an electronic device including at least three filter units as described above, at least two of the at least three filter units being connected in series and being connected in parallel with filter units other than the filter units connected in series.

The quantity of the above-mentioned filter units connected in series and the quantity of the filter units connected in parallel are not particularly limited, and are specifically determined by the volume, type, etc. of the filter. In order to achieve a better filtering effect while avoiding a complicated manufacturing process, as an example, the above-mentioned range of the quantity of filter units connected in series and the range of the quantity of filter units connected in parallel may include three to five. FIG. 13 is illustrated by taking that the filter includes seven filter units, wherein four filter units are connected in series, and the filter units connected in series are connected in parallel with three filter units as an example. Referring to FIG. 13, the filter includes a filter unit B1, a filter unit B2, a filter unit B3, a filter unit B4, a filter unit B5, a filter unit B6, and a filter unit B7. Four filter units are connected in series, namely, the filter unit B1, the filter unit B2, the filter unit B3, and the filter unit B4 are connected in series. The filter units connected in series are connected in parallel with three filter units, namely in parallel with filter unit B5, filter unit B6, and filter unit B7, respectively.

The electronic device described above is suitable for a variety of circuit scenarios based on the glass-based air-gap type, and is not specifically limited herein.

The electronic device provided in the embodiments of the present disclosure greatly simplifies the process manufacturing flow, reduces the process manufacturing procedure difficulty, and is simple and easy to implement.

Embodiments of the present disclosure further provide a manufacturing method for the filter unit as described above.

The method includes steps as follows.

S1, form a substrate.

The material, thickness, and the like of the above-mentioned substrate are not specifically limited herein. As an example, the material of the substrate may include glass, so that a filter unit has the properties of low dielectric loss and high resistivity, helping to improve the insertion loss performance of the filter unit. As an example, the thickness of the substrate may range from 30 μm to 200 μm. Specifically, the thickness of the substrate may be 30 μm, 50 μm, 80 μm, 110 μm, 150 μm, or 200 μm, etc.

S2, form a resonant structure at one side of the substrate, wherein there is a cavity between the resonant structure and the substrate.

The specific structure of the above-mentioned resonant structure is not limited. As an example, with reference to FIG. 5, the above-mentioned resonant structure may include a first electrode 21, a piezoelectric layer 22, and a second electrode 23 which are sequentially arranged in layer configuration. When a voltage (for example, an alternating voltage) is applied to the first electrode 21 and the second electrode 23, the piezoelectric effect converts the electric energy into mechanical energy, thereby making the piezoelectric layer 22 undergo mechanical deformation, thus exciting a bulk acoustic wave in the body of the piezoelectric layer 22. The bulk acoustic wave vibrates at a cavity formed between the modified structure 11 and the resonant structure 2, to perform propagation.

The embodiments of the present disclosure provide a manufacturing method for a filter unit. Compared with a conventional manufacturing method for first forming a groove on the silicon substrate, and then forming and removing a sacrificial layer in the groove to form a cavity, the embodiments of the present disclosure omit the steps of forming a sacrificial layer, removing the sacrificial layer, and like steps and also omit a CMP process, thereby greatly simplifying the process manufacturing flow and reducing the process manufacturing procedure difficulty.

Optionally, the above-mentioned S1, forming a substrate includes:

S11: providing a substrate; and

S12, as shown in FIG. 10, modifying the substrate 1 to form a modified portion 13 and a supporting structure 12, wherein the supporting structure 12 surrounds the modified portion 13.

The above-mentioned process for modifying the substrate is not specifically limited herein. As an example, the process for modifying the substrate may include an etching process, such as a laser-induced etching process. At this time, laser induced etching modification can be performed on only a portion of the substrate. As shown in FIG. 10, a part of the area of the middle of the substrate is modified to form a modified portion 13, and other unmodified portions of the substrate form the supporting structure 12.

When the material of the substrate is glass, the laser-induced etching process can destroy Si—O molecular bonds inside the glass. Then when the substrate is subjected to wet etching, the wet etching rate of the material of the modified portion is much higher than the wet etching rate of the supporting structure, but does not affect the flatness of the surface of the glass substrate, so that a cavity can be formed between the glass substrate and the resonant structure by etching a part of the glass substrate.

By modifying the substrate by using, for example, laser-induced etching technology in the embodiments of the present disclosure, the process manufacturing process may be very effectively simplified, and the process manufacturing procedure difficulty is reduced.

Optionally, the S2 of forming a resonant structure at one side of the substrate, wherein there is the cavity between the resonant structure and the substrate includes:

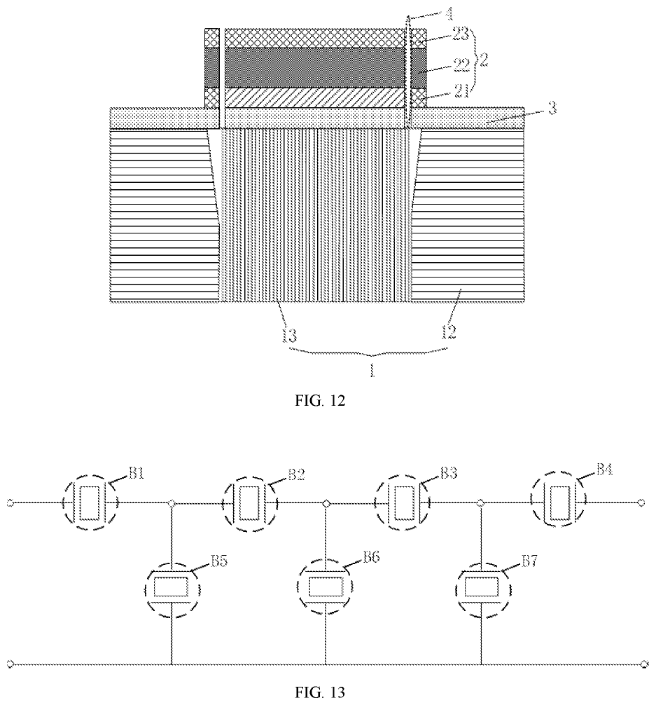

S21, referring to FIG. 12, forming at least one through hole 4 on the resonant structure 2; and

S22, injecting corrosive liquid through the through hole to corrode the modified portion to form a modified structure and a cavity between the modified structure and the resonant structure.

Here, the manufacturing process for forming at least one through hole on the resonant structure is not specifically limited herein. Illustratively, at least one through hole may be formed on the resonant structure by a dry etching process.

Here, the quantity of the through holes is not specifically limited herein. As an example, FIG. 5 is illustrated by taking that the resonant structure 2 includes two through holes 4 as an example, and the quantity and the positions of the through holes can determine the side length, the quantity of spherical centers, the position, etc. of the cambered surface of the surface of the modified structure close to one side of the resonant structure.

Here, the corrosive liquid is not specifically limited herein. Illustratively, the corrosive liquid may include hydrofluoric acid, potassium hydroxide corrosion, etc. Taking the substrate material as glass as an example, the corrosive liquid can corrode the glass substrate to form a cavity. The corrosion rate of the modified structure is fast, a cavity cambered surface structure is formed, and the corrosion rate of adjacent area of the modified structure and the supporting structure is slow, a cavity side surface structure is formed.

It needs to be noted that after S12 of modifying the substrate to form a modified portion and a supporting structure, wherein the supporting structure surrounds the modified portion, and before S21 of forming at least one through hole on the resonant structure, the method further includes:

S13, referring to FIG. 11, forming a supporting layer 3 on the modified portion 13 and the supporting structure 12.

The manufacturing process of the supporting layer is not specifically limited herein. Illustratively, the manufacturing process of the supporting layer may include LPCVD, PECVD, PVD, etc. A silicon nitride supporting layer may be deposited by LPCVD or PECVD, or an aluminum nitride supporting layer may be deposited by PVD.

The material, thickness, and the like of the above-mentioned supporting layer are not specifically limited herein. Illustratively, the material of the supporting layer may include silicon nitride, aluminum nitride, and the like. As an example, the thickness of the supporting layer in the direction perpendicular to the substrate may range from 100 nm to 300 nm. Specifically, the thickness of the supporting layer in the direction perpendicular to the substrate may be 100 nm, 150 nm, 200 nm, 250 nm, or 300 nm, etc.

S14, with reference to FIG. 11, a resonant structure 2 is formed on the supporting layer 3, and the resonant structure 2 includes a first electrode 21, a piezoelectric layer 22, and a second electrode 23, which are sequentially arranged in layer configuration.

The manufacturing process of the resonant structure is not specifically limited herein. As an example, the manufacturing processes of the first electrode and the second electrode may both include PVD, patterning, etc. As an example, the manufacturing process of the piezoelectric layer can include PVD, MOCVD, patterning, etc.

A specific manufacturing method for a filter unit is provided below.

S31, referring to FIG. 10, laser-induced etching is used on the surface of the glass substrate 1 to form the modified portion 13 and the supporting structure 12.

S32, referring to FIG. 11, silicon nitride is deposited on the modified portion 13 and the supporting structure 12 to form the supporting layer 3.

S33, referring to FIG. 11, molybdenum is deposited on the supporting layer 3 to form the first electrode 21.

S34. Referring to FIG. 11, aluminum nitride is deposited on the first electrode 21 to form the piezoelectric layer 22.

S35, referring to FIG. 11, molybdenum is deposited on the piezoelectric layer 22 to form the second electrode 23.

S36, referring to FIG. 12, etching is performed on the second electrode 23, the piezoelectric layer 22, and the first electrode 23 sequentially to form the through hole 4.

S37, hydrofluoric acid flows into the through hole 4 to corrode the glass substrate to form a cavity.

The description of the structure of the filter unit in the embodiments of the present disclosure can refer to the above embodiments, and will not be repeated herein.

A number of specific details are explained in the instructions provided here. However, it is understood that embodiments of the present disclosure may be practiced without these specific details. In some instances, well-known methods, structures and techniques are not shown in detail so as not to obscure the understanding of this specification.

Finally, it should be noted that: the above embodiments are only used to illustrate the technical solution of the present disclosure, and are not limited thereto. Although the present disclosure is described in detail with reference to the foregoing embodiments, those of ordinary skill in the art should understand: they may still modify the technical solutions described in the foregoing embodiments, or equivalently replace some of the technical features. These modifications or replacements do not depart the essence of the corresponding technical solutions from the spirit and scope of the technical solutions of each embodiment of the present disclosure.

1. A filter unit, comprising:
a resonant structure; and
a substrate disposed at one side of the resonant structure, the substrate comprising a modified structure and a supporting structure surrounding the modified structure, and a cavity being formed between the modified structure and the resonant structure.

2. The filter unit according to claim 1, wherein a boundary of an orthographic projection of the resonant structure on the substrate intersects or overlaps with the supporting structure; and
a surface of the modified structure close to one side of the resonant structure comprises at least one cambered surface.

3. The filter unit according to claim 2, wherein the resonant structure comprises at least one through hole communicating with the cavity, a boundary of an orthographic projection of the through hole on the substrate intersecting or overlapping with the modified structure; a geometric center of a space occupied by the through hole is collinear with a spherical center of the cambered surface.

4. The filter unit according to claim 3, wherein the spherical center of the cambered surface is located where the through hole communicates with the cavity.

5. The filter unit according to claim 3, wherein a quantity of the cambered surfaces is the same as a quantity of the through holes.

6. The filter unit according to claim 3, wherein a surface of the supporting structure close to one side of the modified structure comprises an annular surface, a shape of a space enclosed by an edge of the annular surface close to one side of the resonant structure comprises a polygon having rounded corners, and a quantity of edge lengths of the polygon having the rounded corners is the same as a quantity of the through holes and a quantity of the cambered surfaces.

7. The filter unit according to claim 6, wherein the resonant structure has five through holes, the surface of the modified structure close to one side of the resonant structure comprises five cambered surfaces, and the polygon having the rounded corners comprises a pentagon having rounded corners.

8. The filter unit according to claim 7, wherein a distance between a junction of five cambered surfaces and the resonant structure is less than the distance between a position of the cambered surface corresponding to each through hole and the resonant structure.

9. The filter unit according to claim 6, wherein the resonant structure has four through holes, the surface of the modified structure close to one side of the resonant structure comprises four cambered surfaces, and the polygon having the rounded corners comprises a quadrangle having rounded corners; or
the resonant structure has three through holes, the surface of the modified structure close to one side of the resonant structure comprises three cambered surfaces, and the polygon having the rounded corners comprises a triangle having rounded corners.

10. The filter unit according to claim 6, wherein the annular surface comprises a first annular surface and a second annular surface connected to each other, and the second annular surface is located between the first annular surface and the resonant structure; a part of the first annular surface is in direct contact with the modified structure; and the first annular surface is non-coplanar with the second annular surface.

11. The filter unit according to claim 10, wherein a space occupied by the first annular surface is less than a space occupied by the second annular surface.

12. The filter unit according to claim 10, wherein an included angle between the second annular surface and one side of the resonant structure close to the substrate has a range from eighty degrees to eighty-eight degrees.

13. The filter unit according to claim 1, wherein an etching rate of a material of the modified structure is greater than an etching rate of a material of the supporting structure.

14. The filter unit according to claim 3, wherein the filter unit further comprises a supporting layer disposed between the modified structure and the resonant structure; and
the through hole further penetrates through the supporting layer and communicates with the cavity.

15. The filter unit according to claim 1, wherein a material of the modified structure comprises glass.

16. An electronic device comprising at least three filter units according to claim 1, wherein at least two of the at least three filter units are connected in series and are connected in parallel with the filter units other than the filter units connected in series.

17. A manufacturing method for the filter unit according to claim 1, wherein the method comprises:
forming the substrate; and
forming the resonant structure at one side of the substrate, wherein there is the cavity between the resonant structure and the substrate.

18. The manufacturing method for the filter unit according to claim 17, wherein forming the substrate comprises:
providing the substrate; and
modifying the substrate to form a modified portion and a supporting structure, wherein the supporting structure surrounds the modified portion.

19. The manufacturing method for the filter unit according to claim 18, wherein forming the resonant structure at one side of the substrate, wherein there is the cavity between the resonant structure and the substrate comprises:
forming at least one through hole on the resonant structure; and
injecting corrosive liquid through the through hole to corrode the modified portion to form a modified structure and the cavity between the modified structure and the resonant structure.

20. The electronic device according to claim 16, wherein a boundary of an orthographic projection of the resonant structure on the substrate intersects or overlaps with the supporting structure; and
a surface of the modified structure close to one side of the resonant structure comprises at least one cambered surface.
